(19) United States
(12) Patent Application Publication
(10) Pub. No.: US 2021/0255216 A1
(43) Pub. Date: Aug. 19, 2021

(54) PROBE SHEET FOR NON-INVASIVE NANOSCALE ELECTRICAL CHARACTERIZATION

(71) Applicant: Spencer Matonis, Pittsburgh, PA (US)

(72) Inventor: Spencer Matonis, Pittsburgh, PA (US)

(21) Appl. No.: 17/023,085

(22) Filed: Sep. 16, 2020

Related U.S. Application Data
(60) Provisional application No. 62/978,153, filed on Feb. 18, 2020.

(51) Int. Cl. G01R 1/073; B23K 26/34; B33Y 80/00

(52) U.S. Cl. CPC G01R 1/0735; B33Y 80/00; B23K 26/34

(57) ABSTRACT

An apparatus is provided that includes a flexible substrate able to fold upon itself and comprising patterned probe sheet thereon or therein, which is able to conform about microscale topological features of a testing surface. The apparatus provides for the use of patterned conductive probes for surface and sub-surface electrical characterization and the use of a controllable and non-invasive adhesion mechanism for consistent and flush probe contact, such as the use of electroadhesion traces patterned about the testing perimeter or probe vias through the flexible substrate.

### CROSS-REFERENCE TO RELATED APPLICATIONS

The present application claims the benefit of U.S. Provisional Patent Application No. 62/978,153 filed Feb. 18, 2020, which is incorporated by reference in its entirety.

### BACKGROUND OF THE INVENTION

Conductive thin film stacks and electronic microdevices are traditionally characterized with a range of probe stations to verify the quality of functional layers and the performance of patterned components throughout the manufacturing process. The market for automated testing equipment (ATE) used for semiconductor verification and validation (V&V) has increased rapidly in the 21^{st} century [1]. A large portion of this infrastructure tends to come from the nanopositioners and high precision actuators that maneuver a number of delicate probes into contact with the sample surface. ATEs used in industry will oftentimes run for many hours or days straight, characterizing thousands of devices one-by-one. Skilled technicians are needed to keep the machines running properly and a slight bump to the machine will usually result in a recalibration or restarting of the measurement. Manual probe stations for small-scale sample batches, on the other hand, avoid these positioners but require a user to manually lower individual probes to the sample surface. Not only are these setups prone to device and probe damage due to human error, they also limit the speed at which devices can be characterized, the environment in which measurements can take place, and the number of probes that can operate simultaneously for a given sample. Present-day alternatives to cantilever-type, free-standing probes, such as sputtering conductive traces directly on to a sample or using simplistic conductive tape, either cause the sample to be unusable for production or fail to provide sufficient fidelity for nanoscale electrical characterization [2-4].

These deficiencies in measurement capability come at a time of increased market pressure for scalable, non-invasive and adaptable electrical characterization techniques. In particular, specialized characterization systems are needed to help support the increased research and development of technologies such as advanced computing, flexible consumer electronics and medical devices [5]. In the following, a summary and detailed description for a novel sensing platform is provided, along with exemplary Figures of said platform, and a series of measurements that said platform may be used for.

### SUMMARY OF THE INVENTION

The present application addresses these shortcomings of the art by providing an arrangement of conductive probe arrays patterned on a flexible membrane, which may be temporarily adhered to a chip or unpatterned film stack for convenient non-invasive nanoscale electrical characterization. Such a “probe sheet” may accommodate a range of probe designs depending on specific customer needs, and adhere to the surface through a variety of adherence mechanisms for complete and flush probe contact. Potential adhesion mechanisms which will be discussed in further detail include: pneumatic vacuum, electroadhesion distributed piezoelectric-based sheet pressure, thermal expansion or contraction.

The conductive probes of the probe sheet are configured for “nanoscale electrical characterization”, which as used herein refers to the collection of data from a material or device, in which measurements are conducted in the length scale of microns or nanometers and which directly or indirectly indicate, illuminate and/or demonstrate the electrical properties of the material or device.

The probe sheet of the present application provides several benefits, including but not limited to:
i. Customizable probe sheets in accordance with the present application can support small to large-scale batch testing of samples.
ii. Probe sheets may readily accommodate devices of varying geometry, sizes and material design.
iii. The patterned nature of the constituent probe electrodes allows for a higher packing density of measurement probes upon a material surface or device, compared to traditional free-standing probe interfaces.
iv. The comparatively small form factor of a sensor sheet and its supporting hardware allows for convenient electrical characterization within dynamic and harsh environments (e.g., device verification within a cryogenic chamber, under mechanical stress or strain, in vivo or within an electromagnetic field).
v. The use of patterned probe electrodes and an integrated adherence mechanism with no mechanical components means an entire probe sheet can be produced rapidly and at large scale with minimal processing steps.

With its versatile design, a sensor sheet may be utilized for a wide variety of measurement types, including but not limited to: basic conductivity/resistivity measurements; I-V (current-voltage) characteristics; photonics; harmonics; impedance measurements; burn-in stress testing; four-point probe measurements of thin films, including current in-plane tunneling (CIPT) for sub-surface magnetoresistance characterization, Van der Pauw measurements, and Hall effect measurements; and electrical characterization and stimulation of organic membranes such as organ tissue, skin, brain matter, etc. [7-10].

The present application provides for the implementation of a flexible (e.g., able to fold upon itself without fracture) patterned probe sheet that may conform about microscale topological features of the testing surface. The present application further provides for the use of patterned conductive probes for surface and sub-surface electrical characterization and the use of a controllable and non-invasive adhesion mechanism for consistent and flush probe contact, such as the use of electroadhesion traces patterned about the testing perimeter.

In accordance with an aspect of the present application, an apparatus for mounting to a surface for electrical probing of samples is provided. The apparatus comprises a flexible substrate configured to be deformable to a morphology of a testing surface, and one or more conductive probes arranged within and/or atop the flexible substrate, each of the one or more conductive probes configured for nanoscale electrical characterization.

In accordance with various embodiments of the apparatus, the flexible substrate is made from one of thermoplastic polyurethane, silicone rubber, hydrogel film, polyimide film or polyethylene film. The flexible substrate may also be non-conductive and non-reactive to ambient air or moisture. The apparatus is further configured to be foldable upon itself without fracture. The one or more conductive probes are configured within and/or atop the flexible substrate so as to be flexible in tandem with the flexible substrate. In accordance with various embodiments of the apparatus of the present application, the flexible substrate and the one or more conductive probes have a substantially similar thermal expansion coefficient to prevent damage to either of the flexible substrate or the one or more conductive probes.

In various embodiments of the apparatus, the apparatus comprises a dry adherence mechanism configured to reversibly adhere the apparatus to the testing surface. In one such embodiment, the dry adherence mechanism comprises an electroadhesion mechanism, the electroadhesion mechanism comprising alternating lines of applied voltage bias applied through an external source patterned on the flexible substrate and configured to create a localized force of attraction between the flexible substrate and the testing surface. In a further such embodiment, the dry adherence mechanism comprises a ring or a channel about a perimeter of the flexible substrate in communication with a vacuum pump configured to remove air from the ring or the channel thereby reversibly adhering the apparatus to the testing surface via a vacuum suction. In another such embodiment, the dry adherence mechanism comprises a piezoelectric material deposited on a second surface of the flexible substrate opposing a first surface of the flexible substrate comprising the one or more conductive probes and configured to apply a downward pressure on the one or more probes towards the testing surface. In a still further such embodiment, the flexible substrate is made of a first material and the dry adherence mechanism comprises a second material applied on a second surface of the flexible substrate opposing a first surface of the flexible substrate comprising the one or more probes, the second material configured to apply a downward pressure on the one or more conductive probes towards the testing surface by way of a thermal gradient. In further such embodiments, the dry adherence mechanism comprises an external applicator system configured to apply a downward pressure on the one or more conductive probes towards the testing surface by way of mechanical pressure, or the apparatus may be used in combination with such an external applicator system. In the aforementioned embodiments, the dry adherence mechanism is non-invasive to the testing surface and provides uniform probe contact with one or more devices on the testing surface.

In accordance with further embodiments of the apparatus, which may be in combination with or in alterative to any of the above-described embodiments, the flexible substrate further comprises interfacial vias formed through the substrate for the one or more conductive probes. Manufacturing the flexible substrate with interfacial vias is performed by utilizing a combination of micromachining and additive ink-based printing techniques.

In accordance with further embodiments of the apparatus, which may be in combination with or in alterative to any of the above-described embodiments, the apparatus further comprises an interconnection cable configured to: receive data measured by the one or more conductive probes and provide the data measured to an external computing system for processing; and receive measurement control signals from the external computing system for providing to the one or more conductive probes.

In accordance with embodiments of the apparatus, the one or more conductive probes configured for nanoscale electrical characterization are configured to measure one or more of conductivity, resistivity, current, voltage, photonics, harmonics or impedance. Additionally or alternatively, the one or more conductive probes configured for nanoscale electrical characterization are configured to perform thin film measurements, including one or more of current in-plane tunneling for sub-surface magnetoresistance characterization, Van der Pauw measurements, and Hall effect measurements.

### BRIEF DESCRIPTION OF THE FIGURES

FIG. 1 shows an embodiment of a probe sheet and testing samples, according to the present application.

FIG. 2A shows an example of an electroadhesion pattern for probe application according to the present application.

FIG. 2B shows a cross-sectional view of an embodiment of a probe sheet having multiple electroadhesion rings, with an indicator for applied voltage to the bias rings, which is adhered to the testing surface.

FIG. 3 shows a cross-sectional view of an embodiment of a probe sheet having vacuum channels, which is adhered to a testing surface.

FIG. 4 shows a cross-sectional view of an embodiment of a probe sheet having a piezoelectric material, which is adhered to a testing surface.

FIG. 5A shows a cross-sectional view of a first embodiment of a probe sheet, which is adhered to a testing surface by a temperature gradient.

FIG. 5B shows a cross-sectional view of a further embodiment of a probe sheet, which is adhered to a testing surface by a temperature gradient.

FIG. 6A shows a cross-sectional view of a first embodiment of a simplified probe sheet, which demonstrates the use of conductive vias patterned through the sheet substrate to interface with the testing surface.

FIG. 6B shows a cross-sectional view of a further embodiment of a simplified probe sheet, which demonstrates the use of conductive vias patterned through multiple layers of sheet substrate to interface with the testing surface.

### DETAILED DESCRIPTION OF THE FIGURES

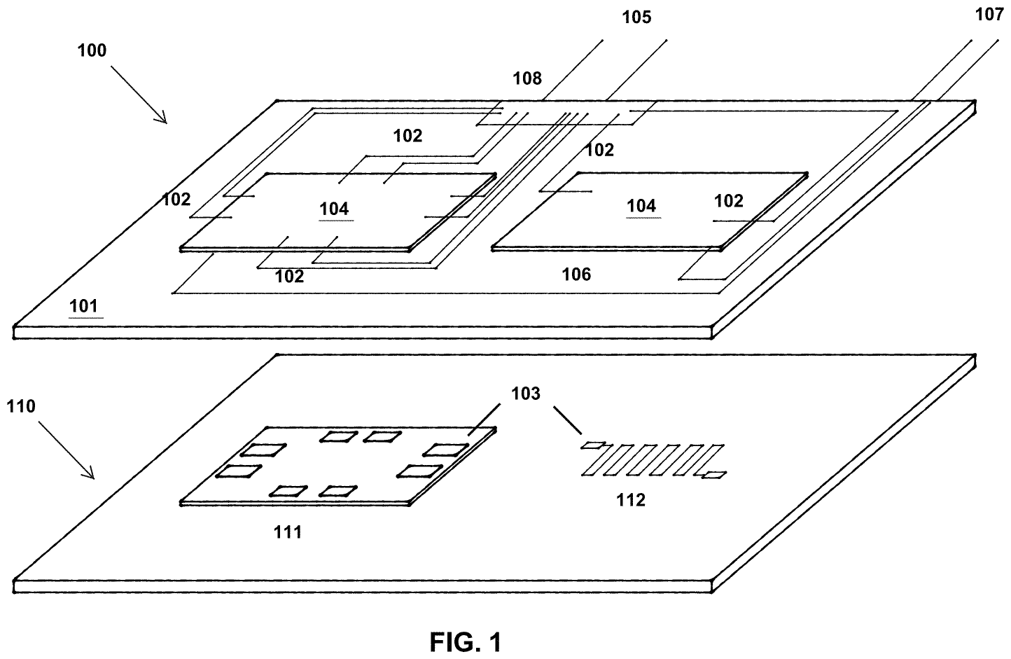

The probe sheet of the present application will now be described with reference made to FIGS. 1-6B.

An example of a custom, probe sheet 100 in accordance with the present application is shown in FIG. 1. In the described embodiment, the probe sheet 100 is adaptable to different surfaces, environments, device geometries and probe techniques, while also being non-invasive and inexpensive and to manufacture.

The sheet 100 comprises a flexible substrate 101, a multitude of probes 102, and the adhesion area 104, which may include but is not limited to architectures such as: additional conductive traces on either side of the substrate 101, specialized films or internal pressure channels, depending on the adhesion mechanism used. Adhesion support lines 106, such as vacuum channels or electrical lines establish the transition between the adhesion area 104 architecture to the outbound adhesion control cable 107, which the user may interface with. In a similar fashion, the probe sheet 100 may also include a data or interconnection cable 105, which may be separate from or integrated with the adhesion control cable 107. This interconnection cable 105 and its interconnection point 108 form the transition from patterned sheet architecture, responsible for data collection, to the external user control system, responsible for data processing and measurement control. The substrate 101 of the probe sheet 100 must be non-reactive, non-conductive or dielectric (so it does not interfere with measurements), and leave minimal residue upon detachment of the sheet 100 from a surface.

The substrate 101 can be made from any one of several materials, including for example: thermoplastic polyurethane (TPU), silicone rubber, hydrogels, and polyimide (PI) or polyethylene films.

The probes of the conductive probe array 102 may be composed of gold (Au), silver (Ag), platinum (Pt) or Copper (Cu) material, which may be sputtered with a mask, patterned via photolithography, or additively manufactured with the use of conductive inks. It is worth nothing that the sheet 100 and its constituent probes 102 are made of materials and deposited thinly enough such that the sticker 100 and probe 102 patterns are able to flex in-tandem to prevent fracture. Additionally, for use in dynamic or extreme temperature environments, the substrate 101 and electrode 102 materials of the patch 100 should have similar thermal expansion coefficients to prevent cracking or plastic deformation of either material. The conductive probes 102 are configured for nanoscale electrical characterization to collect data from a sample to demonstrate the electrical properties of the material of sample with nanoscale probe measurements.

While many of the Figures illustrate probe sheets 100 poised to characterize a relatively small number of devices or samples using a proportionally limited number of probes 102, the design principles described should allow for a highly scalable measurement platform. This includes one in which a sheet 100 may contain a probe array 102 arranged to characterize a hundred or more devices or samples at once. In some embodiments, it is expected that the adhesion area 104 and associated mechanism may be individualized about each device or sample, while in other embodiments, the adhesion area 104 may constitute the majority of the probe sheet, thereby facilitating the measurement of samples in bulk.

### Adherence Mechanisms

A number of adherence mechanisms can be used to for controlled fastening of the sensor patch 100 to a testing surface 110, which in the example shown in FIG. 1 includes two test devices 111, 112 and their corresponding I/O pads or electrodes 103. The primary requirements for this “dry” adherence mechanism include the following: stable and uniform probe contact must be established with the points of interface 103; the mechanism must be reversible by the user for removal of the sensor patch 100; and in order to be considered “non-invasive”, the adherence mechanism should leave no residue behind and the characterized surface 110 must be left unaltered in both its physical and electrical properties following the sensor 100 attachment and detachment. Similarly, when the adherence mechanism is active, it should not contribute significant noise or interference with the measurement being run, nor should it cause lasting damage to any device being characterized.

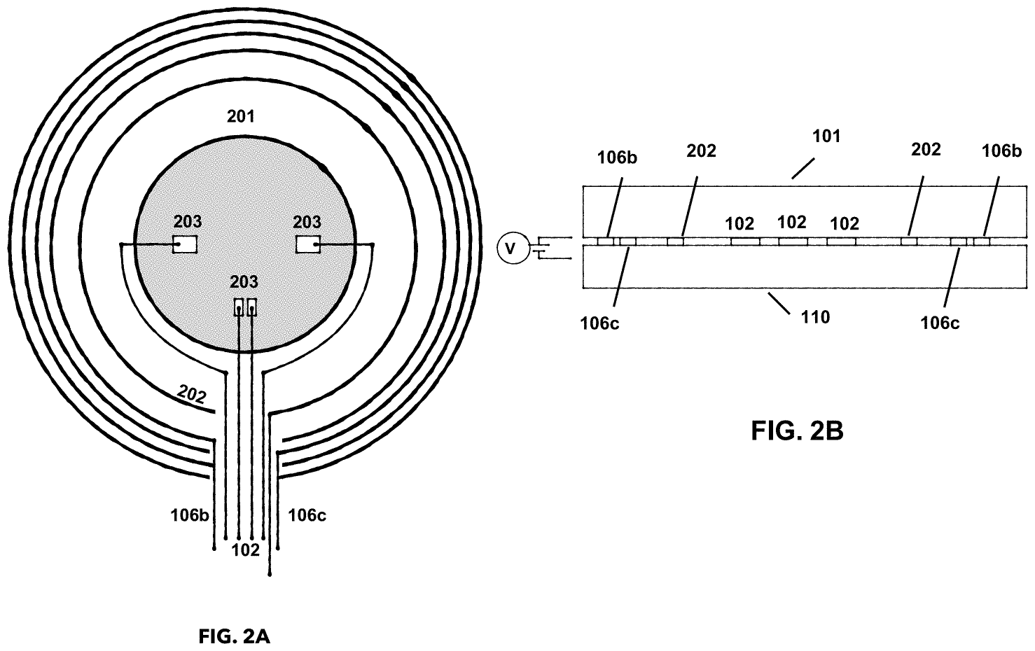

It is noted that in FIG. 1, the orientation of the sensor patch 100 is presented so as to illustrate the elements on the testing surface of the sensor sheet 100 comprising the conductive probe array 102, but in use, the illustrated surface of the sensor sheet 100 shown in FIG. 1 would be oriented facing the surface of the testing substrate 110 shown in FIG. 1. Further, as the purpose of FIG. 1 is to illustrate the application and orientation of the sheet as a whole, as such, the adhesion area 104 has been illustrated in a more generalized form for purposes of providing an overview, with more detailed diagrams of various possible mechanisms for this region following in FIGS. 2A-5B.

With these design criteria described for effective, non-invasive and controllable sensor sheet adherence, potential adherence mechanisms are described below, as well as a mechanical application of the probe sheet to a testing surface:

i. Electroadhesion

An electroadhesion mechanism (sometimes referred to as dry adhesion or dynamic electrostatic attraction) can be used in a similar manner to present-day chuck handling systems, such as Coulomb-force electrostatic chucks or Johnsen-Rahbek electrostatic chucks, instruments sometimes used for delicate wafer handling [11-13]. An example of an electroadhesion pattern for probe application is illustrated in FIG. 2A, and an example of such a probe sheet 100 adhered to a test surface 110 is shown in FIG. 2B. In particular, FIG. 2A shows a top-down view of a probe sheet applied to a sample device 201 for testing the sample device 201. With this mechanism, alternating lines 106b, 106c of DC bias (applied through an external source) are patterned on a dielectric substrate and used to create a localized force of attraction between the patterned substrate and sample surface 201 having testing pads 203. For use within a flexible probe sticker, this pattern of alternating bias may decorate the perimeter of the sensing substrate and lie outside of a conductive “grounding ring” 202, which acts to absorb stray charge and prevent interference with the electrical measurement. Three or more wires (positive bias 106b, negative bias 106c and ground 202) may exit the device via the adhesion control cable 107 to an external power source and ground. Two drawbacks to the electroadhesion adherence mechanism include its dependence on high voltage, which may interfere with the device or electrical measurement if not properly contained; and its dependence upon a flat or uniform adherence surface to prevent dielectric and electrostatic breakdown.

This mechanism is advantageous as it requires no additional processing techniques, the attraction forces are easily tuned, and the dielectric substrates it necessitates are the optimal sheet material for a flexible sensor probe patch.

ii. Vacuum Suction

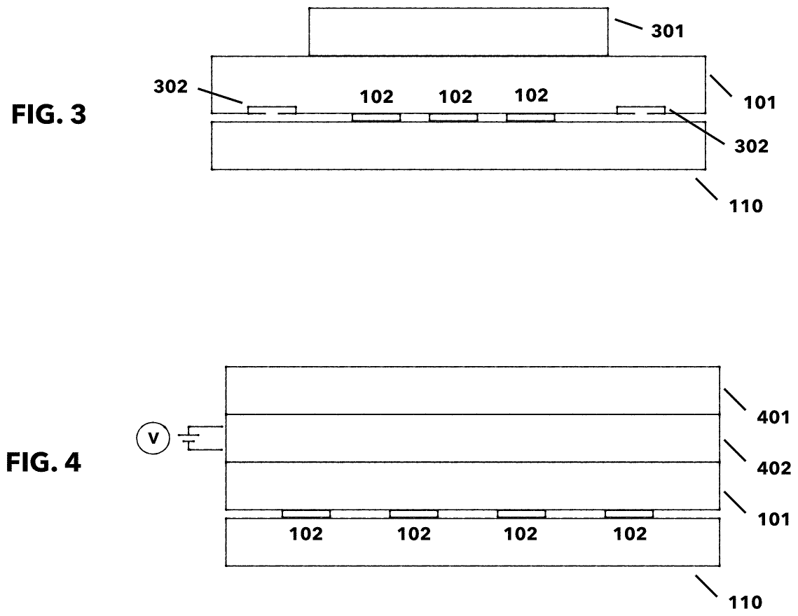

An alternative and versatile adherence mechanism is the use of pneumatic vacuum or suction to secure the probe sheet and bring the patterned probes into contact with the testing surface. One embodiment of this application, shown in FIG. 3, uses a thin perforated ring 302 of substrate about the perimeter of the substrate 101 and the testing area 110 through which air is sucked through via an external vacuum pump (not shown). This is an attractive technique due its simplicity, lack of mechanical or electrical components in the sensing area 110, and minimal external infrastructure. The downside to this technique is that it is not sufficient in ultra-high vacuum testing environments and it requires extra manufacturing steps in order to create the perforated vacuum channel 302 shown in FIG. 3. The use of pneumatic force for patterned probe application can be taken a step further with the use of an inflatable “microbladder” 301 on a surface of the substrate 101 opposite the probe area 102. With this addition, vacuum may be pulled through the perforated perimeter channel 302 to be the probes 102 oriented, while a complementary bladder 301 may be positioned on the backside of the flexible substrate 101 in order to inflate towards the test sample 110. The result is a uniform and controllable probe pressure in the Z axis in order to ensure stable probe 102 contact with the testing sample 110.

iii. Piezoelectric Pressure Much in the same way atomic force microscope cantilevers use piezoelectric coatings for controlled movement, a network of piezoelectric material 402 may be deposited on the backside of the probe sticker 100 (opposite the testing surface having the probe array 102) in order to apply distributed downward pressure on to the sensing area 110 for strong probe contact [14]. An example of this embodiment of the probe sticker 100 is shown in FIG. 4. A layer of piezoelectric material 402 is applied on the surface of the substrate 101 opposite the surface having the probe array 102, the piezoelectric material being connected to a voltage supply, and a further layer of a more rigid, capping material 401 is applied on an exposed surface of the piezoelectric material 402. This is a similar application as using a piezoelectric actuator or cantilever, where displacement is generated through a relatively low applied voltage to the piezoelectric material 402, which can be adjusted to high accuracy. The downsides are that this method requires using an additional, more exotic and typically less flexible material type (e.g. PZT) and that the sheet may not necessarily be held as strongly in place as it would be with vacuum or electroadhesion mechanisms.

iv. Thermal Expansion or Contraction

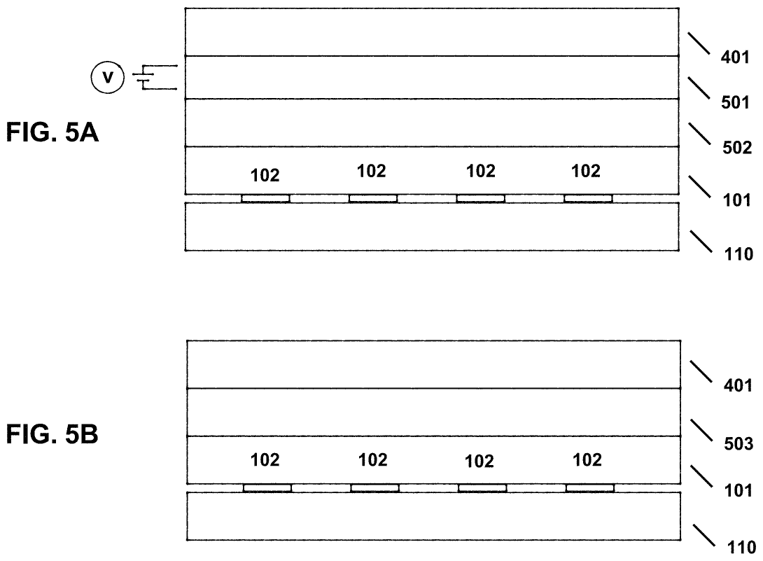

Probe pressure and associated patch adhesion may also be achieved using a thermal gradient in two manners. Firstly, as shown for example in FIG. 5A, an effectively “rigid” layer of material 401 with a low coefficient of thermal expansion (CTE) may be applied to the backside of the sticker sheet, above the testing area. Next, a uniform layer 501 or printed thermistor pattern can be used to apply localized heat to the material layers. Finally, a layer 502 of a material of high CTE relative to the “rigid” layer 401 is included. The sheet probes 102 can be directly patterned to this material, or they may be applied to an intermediary flexible layer 101, as shown in FIG. 5A. Like a bimetallic strip, the high CTE layer 502 will expand more than its “rigid” counterpart 401 and a downward pressure will be applied, establishing sufficient probe 102 contact against the testing surface 110. The effectiveness of this method will decrease in extreme temperatures and, like the piezoelectric network, will not necessarily hold the entire sheet firmly in place, and thus may be paired with additional mechanisms for complete adhesion. A secondary, more simplified, approach, shown for example in FIG. 5B, may utilize the negative CTE of a layer 503 of materials such as silicon or germanium at low temperatures, in combination with a rigid layer 401, to apply similar back pressure to the probing area 102.

In order to accommodate the demands for high density probe arrays 102 or high throughput sample 103 characterization, it may be preferable to some users to utilize a mechanical adhesion mechanism in order to establish probe 102 contact and sheet 100 adhesion.

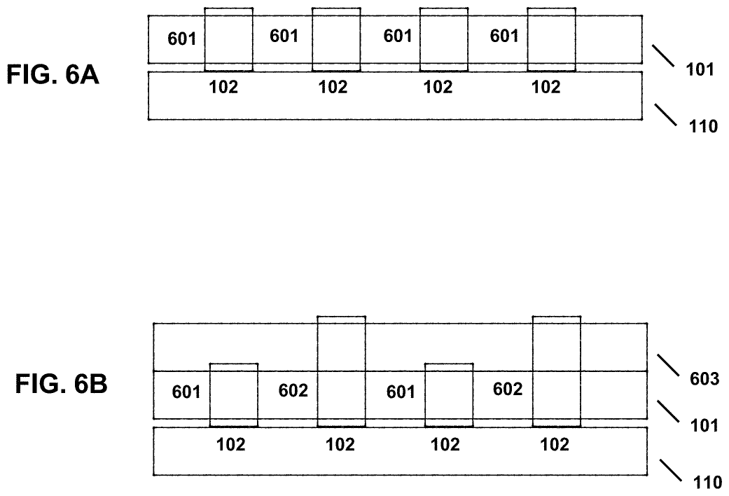

As the cross-sectional view in FIG. 6A reflects, the sheet architecture does not require an internal or patterned adhesion mechanism 104. Rather, in this embodiment, the flexible substrate 101 can be pressed down by an external “applicator” system (not shown) in order to bring the probe array 102 into stable contact with the appropriate points of interface 103. Non-specific to this methodology of mechanical-based sheet pressure, FIG. 6A and FIG. 6B also illustrate the use of patterned probe vias 601, 602 which may run through either or both of the primary substrate 101 and secondary substrate 603. In FIG. 6A, the probes 102 of the sheet are not patterned only on one side of the substrate 101, but also go along the back side of the substrate 101 and then can be pressed through at the point of interface with the sample 110. FIG. 6B exhibits that multiple substrates 101, 603 can be layered with vias 601, 602 so that channels can go under each other, to provide an even higher probe density.

The use of such vias 601, 602 effectively increases the allowable probe density of a sheet 100 and reduces the need for devices to have purely peripheral I/O pads 103. As channels through the substrate layers 101, 603, the probe vias 601, 602 consume less area when compared to the sheet 100 of FIG. 1, for example, and may occupy multiple planes of patterning as they run along multiple substrate layers 101, 603 before convening at the common interconnection point 108 and associated outbound data cable 105. In the sheet 100 of FIG. 1, the channels for probes 102 come from the edges of the substrate 101 and are only on one side of the substrate 101, such that fewer probes can be provided and that only peripheral pads can be tested, as the probe channels are coming from the edges. Probes in the form of vias means that more channels can be fit and the ends of those channels brought into the device array without crossing over other elements on the substrate.

It is noted that the embodiments illustrated in FIGS. 6A and 6B are not necessarily an independent probe sheet design when compared to the sheets illustrated in other Figures, but the probe sheet design can be used in conjunction with the embodiments shown and described above, and the probe layering can be applied in tandem with any of the adhesion mechanisms described herein.

### Methods of Manufacturing

The probe sheet 100 and its constituent materials, as described, may be combined and manufactured in a variety of ways. Modern ink-based printing methods (such as Gravure printing, roll-to-roll processing, inkjet printing, screen printing and aerosol jet printing) lend themselves particularly well to high throughput production of flexible sensor arrays with rapid design iteration. Functional conductive inks (using metals like Au and Ag) designed for these printed processes are well documented and capable of being patterned with micron-scale resolution that is sufficient for interfacing with industry standard I/O pads.

For the sheet architectures shown in FIG. 6A and FIG. 6B, aerosol jet printing combined with precision laser micromachining is a practical method of sheet fabrication. Using a laser tool, via channels can be made through the substrate(s) material and be subsequently filled in using a conductive aerosol spray.

For smaller probe types or probes composed of exotic materials, conventional thin film deposition techniques such as sputtering or photolithography may be used. It is important to note that with any of these deposition methods for the probe materials and associated architecture, the probes should ideally be slightly thicker than, or flush with, the adhesion mechanism on the sample side (when applicable) to ensure proper probe contact with the testing surface. For example, if the patterned electroadhesion rings of FIG. 2A extend 30 μm from the substrate and the probes extend 10 μm, when the adhesion is turned on, the probes would remain “floating” above the surface, preventing sample characterization. For the methods which apply an associated “back pressure” to the probes towards the testing surface(s), this problem can be ignored.

In summary, the low profile and flexible nature of the probe sheet, when coupled with a non-invasive or integrated adherence mechanism, allows for the characterization of thin film stacks or electronic devices in a variety of environments, including but limited to: in vacuum, at cryogenic temperatures, in microgravity or within a magnetic field. Additionally, the small form factor of the sheet and flexible nature of the patterned probes minimize the risk of sample or probe damage, while allowing for fast and versatile probe sheet manufacturing via some of the methods described.

While there have been shown and described and pointed out fundamental novel features of the invention as applied to preferred embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice.

### WORKS CITED

1. Russell, Damon, Kieran Cleary, and Rodrigo Reeves. “Cryogenic probe station for on-wafer characterization of electrical devices.” Review of Scientific Instruments 83.4 (2012): 044703.
2. Lee, Ching-Ming, et al. “Current-in-plane tunneling measurement through patterned contacts on top surfaces of magnetic tunnel junctions.” Journal of Magnetics 16.2 (2011): 169-172.
3. Bregman, Mark F., et al. “Integrated circuit testing system having a cantilevered contact lead probe pattern mounted on a flexible tape for interconnecting an integrated circuit to a tester.” U.S. Pat. No. 5,189,363. 23 Feb. 1993.
4. McCormick, John. “Multi-layer tab tape having distinct signal, power and ground planes and wafer probe card with multi-layer substrate.” U.S. Pat. No. 5,550,406. 27 Aug. 1996.
5. Nathan, Arokia, et al. “Flexible electronics: the next ubiquitous platform.” Proceedings of the IEEE 100.Special Centennial Issue (2012): 1486-1517.
6. Worledge, D. C., and P. L. Trouilloud. “Magnetoresistance measurement of unpatterned magnetic tunnel junction wafers by current-in-plane tunneling.” Applied Physics Letters 83.1 (2003): 84-86.
7. Ramadan, A. A., R. D. Gould, and A. Ashour. “On the Van der Pauw method of resistivity measurements.” Thin Solid Films 239.2 (1994): 272-275.
8. Petersen, Dirch H., et al. “Micro-four-point probe Hall effect measurement method.” Journal of Applied Physics 104.1 (2008): 013710.
9. Bettinger, Christopher J. “Recent advances in materials and flexible electronics for peripheral nerve interfaces.” Bioelectronic Medicine 4.1 (2018): 6.
10. Podhaj sky, Ronald J. “System and method of using thermal and electrical conductivity of tissue.” U.S. Pat. No. 9,375,246. 28 Jun. 2016.
11. Pelrine, Ronald E., et al. “Electroadhesive devices.” U.S. Pat. No. 8,125,758. 28 Feb. 2012.
12. Dadkhah, Mohammad, et al. “Increasing adhesion via a new electrode design and improved manufacturing in electrostatic/microstructured adhesives.” Journal of Electrostatics 91 (2018): 48-55.
13. Zhou, Yu Sheng, et al. “Manipulating nanoscale contact electrification by an applied electric field.” Nano letters 14.3 (2014): 1567-1572.
14. Rogers, B., et al. “Improving tapping mode atomic force microscopy with piezoelectric cantilevers.” Ultramicroscopy 100.3-4 (2004): 267-276.

What is claimed:

1. An apparatus for mounting to a surface for electrical probing of samples, comprising:
a flexible substrate configured to be deformable to a morphology of a testing surface; and
one or more conductive probes arranged within and/or atop the flexible substrate, each of the one or more conductive probes configured for nanoscale electrical characterization.

2. The apparatus according to claim 1, wherein the flexible substrate is made from one of thermoplastic polyurethane, silicone rubber, hydrogel film, polyimide film or polyethylene film.

3. The apparatus according to claim 1, wherein the flexible substrate is non-conductive and non-reactive to ambient air or moisture.

4. The apparatus according to claim 1, wherein the apparatus is configured to be foldable upon itself without fracture.

5. The apparatus according to claim 1, further comprising a dry adherence mechanism configured to reversibly adhere the apparatus to the testing surface.

6. The apparatus according to claim 5, wherein the dry adherence mechanism is non-invasive to the testing surface and provides uniform probe contact with one or more devices on the testing surface.

7. The apparatus according to claim 5, wherein the dry adherence mechanism comprises an electroadhesion mechanism, the electroadhesion mechanism comprising alternating lines of applied voltage bias applied through an external source patterned on the flexible substrate and configured to create a localized force of attraction between the flexible substrate and the testing surface.

8. The apparatus according to claim 5, wherein the dry adherence mechanism comprises a ring or a channel about a perimeter of the flexible substrate in communication with a vacuum pump configured to remove air from the ring or the channel thereby reversibly adhering the apparatus to the testing surface via a vacuum suction.

9. The apparatus according to claim 5, wherein the dry adherence mechanism comprises a piezoelectric material deposited on a second surface of the flexible substrate opposing a first surface of the flexible substrate comprising the one or more conductive probes and configured to apply a downward pressure on the one or more probes towards the testing surface.

10. The apparatus according to claim 5, wherein flexible substrate is made of a first material and the dry adherence mechanism comprises a second material applied on a second surface of the flexible substrate opposing a first surface of the flexible substrate comprising the one or more probes, the second material configured to apply a downward pressure on the one or more conductive probes towards the testing surface by way of a thermal gradient.

11. The apparatus according to claim 5, wherein the dry adherence mechanism comprises an external applicator system configured to apply a downward pressure on the one or more conductive probes towards the testing surface by way of mechanical pressure.

12. The apparatus according to claim 1, wherein the flexible substrate further comprises interfacial vias formed through the substrate for the one or more conductive probes.

13. The apparatus according to claim 12, wherein manufacturing of the flexible substrate with interfacial vias is performed by utilizing a combination of micromachining and additive ink-based printing techniques.

14. The apparatus according to claim 1, further comprising an interconnection cable configured to:
receive data measured by the one or more conductive probes and provide the data measured to an external computing system for processing; and
receive measurement control signals from the external computing system for providing to the one or more conductive probes.

15. The apparatus according to claim 1, wherein the flexible substrate and the one or more conductive probes have a substantially similar thermal expansion coefficient to prevent damage to either of the flexible substrate or the one or more conductive probes.

16. The apparatus according to claim 1, wherein the one or more conductive probes are configured within and/or atop the flexible substrate so as to be flexible in tandem with the flexible substrate.

17. The apparatus according to claim 1, wherein the one or more conductive probes configured for nanoscale electrical characterization are configured to measure one or more of conductivity, resistivity, current, voltage, photonics, harmonics or impedance.

18. The apparatus according to claim 1, wherein the one or more conductive probes configured for nanoscale electrical characterization are configured to perform thin film measurements, including one or more of current in-plane tunneling for sub-surface magnetoresistance characterization, Van der Pauw measurements, and Hall effect measurements.
